(19) United States
(12) Patent Application Publication
(10) Pub. No.: US 2010/0079359 A1
(43) Pub. Date: Apr. 1, 2010

(54) SEMICONDUCTOR LASER DEVICE AND DISPLAY

(75) Inventors: Yasumitsu Kunoh, Hirakata-shi (JP); Yasuhiko Nomura, Osaka-shi (JP)

Correspondence Address: MOTS LAW, PLLC, 1629 K STREET N.W., SUITE 602, WASHINGTON, DC, 20006-1635, US

(73) Assignee: SANYO ELECTRIC CO., LTD., Moriguchi-shi (JP)

(21) Appl. No.: 12/570,662

(22) Filed: Sep. 30, 2009

(30) Foreign Application Priority Data
Sep. 30, 2008 (JP) 2008-251967
Aug. 28, 2009 (JP) 2009-198151

(51) Int. Cl. H01S 5/40; G09G 3/20

(52) U.S. Cl. 345/55; 372/50.121

(57) ABSTRACT

This semiconductor laser device includes a substrate, a blue semiconductor laser element, formed on the surface of a substrate, including a first active layer made of a nitride-based semiconductor and having a first major surface of a non-C plane and a green semiconductor laser element, formed on the surface of the substrate, including a second active layer made of a nitride-based semiconductor and having a second major surface of a surface orientation substantially identical to the non-C plane.

### CROSS-REFERENCE TO RELATED APPLICATIONS

The priority application numbers JP2008-251967, semiconductor laser device, Sep. 30, 2008, Yasumitsu Kunoh et al. and JP2009-198151, semiconductor laser device, Aug. 28, 2009, Yasumitsu Kunoh et al., upon which this patent application is based are hereby incorporated by reference.

### BACKGROUND OF THE INVENTION

1. Field of the Invention

The present invention relates to a semiconductor laser device and a display, and more particularly, it relates to a semiconductor laser device formed by integrating a plurality of semiconductor laser elements and a display including the same.

2. Description of the Background Art

While miniaturization of a device such as a projector has recently been increasingly required, development of a projector and a display each employing semiconductor laser elements as red (R), G (green) and B (blue) light sources is advanced. In order to miniaturize the device and to reduce the number of components constituting the same, it is attempted to employ semiconductor laser elements capable of directly utilizing the wavelengths of light sources as the light sources without employing a system of generating desired emission wavelengths with light sources and wavelength conversion elements converting the wavelengths of the light sources. In the case of employing the semiconductor laser elements as the light sources, employment of a monolithic semiconductor laser device prepared by forming a plurality of semiconductor laser elements on the same substrate is also attempted.

In general, therefore, a monolithic semiconductor laser device formed by integrating a blue semiconductor laser element and a green semiconductor laser element on the surface of the same substrate is proposed, as disclosed in Japanese Patent Laying-Open No. 2007-227652, for example.

Japanese Patent Laying-Open No. 2007-227652 discloses a monolithic double-wavelength semiconductor light-emitting device (semiconductor laser device) prepared by forming a first semiconductor laser (blue semiconductor laser element) including a first active layer having a first well layer of InGaN and a second semiconductor laser (green semiconductor laser element) including a second active layer having a second well layer of InGaN and having a larger oscillation wavelength than the first semiconductor laser on the surface of the same substrate. Japanese Patent Laying-Open No. 2007-227652 neither discloses nor suggests which crystal planes are employed for defining the major surfaces when forming the first active layer of the first semiconductor laser and the second active layer of the second semiconductor laser.

In the double-wavelength semiconductor light-emitting device disclosed in the aforementioned Japanese Patent Laying-Open No. 2007-227652, however, piezoelectric fields generated by piezoelectric polarization resulting from strains of crystal lattices are increased if the first and second active layers are formed on a c-plane ((0001) plane) which is a polar plane, and hence energy bands in the first and second well layers of the first and second active layers are extremely inclined due to the piezoelectric fields. The quantities of changes in band gaps between the bottoms of conduction bands and the tops of valence bands in the first and second well layers are proportional to the inclinations of the energy bands in the first and second well layers and the thicknesses of the first and second well layers. When the energy bands are remarkably inclined, therefore, the quantities of changes in the band gaps are more increased with respect to the quantities of changes in the thicknesses of the first and second well layers. Consequently, the quantities of changes (widths of fluctuations) in oscillation wavelengths of the first and second semiconductor lasers with respect to the quantities of changes in the thicknesses of the first and second well layers of the first and second active layers are increased. Therefore, the thicknesses of the first and second well layers of the first and second active layers are dispersed, and hence the oscillation wavelengths of the first and second semiconductor lasers are easily dispersed every semiconductor laser device. The first and second semiconductor lasers are formed on the same substrate. If either the first semiconductor laser or the second semiconductor laser has an oscillation wavelength exceeding a reference range, therefore, the whole of a monolithic semiconductor laser element portion is out of the reference range. Therefore, the yield of the semiconductor laser device including the first and second semiconductor lasers formed on the same substrate may conceivably be disadvantageously reduced.

### SUMMARY OF THE INVENTION

A semiconductor laser device according to a first aspect of the present invention includes a substrate, a blue semiconductor laser element, formed on a surface of the substrate, including a first active layer made of a nitride-based semiconductor and having a first major surface of a non-C plane and a green semiconductor laser element, formed on the surface of the substrate, including a second active layer made of a nitride-based semiconductor and having a second major surface of a surface orientation substantially identical to the non-C plane. In the present invention, the term “non-C plane” indicates a wide concept including all crystal planes other than a c-plane ((0001) plane) which is a polar plane, and includes non-polar (H,K,—H—K,O) planes such as an m-plane ((1-100) plane) and an a-plane ((11-20) plane) and planes (semipolar planes) inclined from the c-plane ((0001) plane).

In the semiconductor laser device according to the first aspect of the present invention, as hereinabove described, the first and second active layers, made of the nitride-based semiconductors, of the blue and green semiconductor laser elements formed on a surface of the same substrate have the first and second major surfaces of non-C planes of substantially identical surface orientations, respectively, whereby piezoelectric fields generated in the first and second active layers can be reduced as compared with a case where the first and second active layers have the first and second major surfaces of c-planes which are polar planes, respectively. Thus, inclinations of energy bands in the first and second active layers resulting from the piezoelectric fields can be reduced, whereby the quantities of changes (widths of fluctuations) in oscillation wavelengths of the blue and green semiconductor laser elements can be more reduced. Consequently, reduction of the yield of the integrated semiconductor laser device including the blue and green semiconductor laser elements formed on the surface of the same substrate can be suppressed.

In the aforementioned semiconductor laser device according to the first aspect, the first active layer preferably has a quantum well structure including a first well layer having a compressive strain, the second active layer preferably has a quantum well structure including a second well layer having a compressive strain, and a thickness of the first well layer is preferably larger than a thickness of the second well layer. According to this structure, the oscillation wavelengths of the blue and green semiconductor laser elements are shifted toward shorter sides than the peak wavelengths thereof as compared with a case where the blue and green semiconductor laser elements are formed on c-planes ((0001) planes), since influences exerted by piezoelectric fields are small on non-C planes. In order to shift the oscillation wavelengths of the blue and green semiconductor laser elements toward longer sides, therefore, the compressive strains of the first and second well layers of the blue and green semiconductor laser elements must be increased as compared with those in the case where the blue and green semiconductor laser elements are formed on the c-planes. Further, the oscillation wavelength of the green semiconductor laser element is larger than that of the blue semiconductor laser element, and hence the compressive strain of the second well layer of the green semiconductor laser element must be rendered larger than that of the first well layer of the blue semiconductor laser element when the first and second well layers having the compressive strains are formed. In this case, in-plane compressive strains of the first and second well layers are increased, and hence misfit dislocations are easily formed in the first and second well layers. Further, the second well layer of the green semiconductor laser element has the compressive strain larger than that of the first well layer of the blue semiconductor laser element, and easily causes crystal defects. Therefore, the thickness of the second well layer easily causing crystal defects due to the large compressive strain can be reduced by rendering the thickness of the first well layer of the first active layer of the blue semiconductor laser element larger than that of the second well layer of the second active layer of the green semiconductor laser element, whereby formation of crystal defects can be suppressed in the second well layer of the green semiconductor laser element.

In this case, the first well layer is preferably made of a nitride-based semiconductor containing In, and is more preferably made of InGaN. According to this structure, a blue semiconductor laser element having a higher efficiency can be prepared.

In the aforementioned semiconductor laser device including the first and second active layers having the first and second well layers, respectively, the second well layer is preferably made of a nitride-based semiconductor containing In, and is more preferably made of InGaN. According to this structure, a green semiconductor laser element having a higher efficiency can be prepared.

In the aforementioned semiconductor laser device according to the first aspect, the non-C plane is preferably substantially a (11-22) plane. According to this structure, the quantities of changes in the oscillation wavelengths of the blue and green semiconductor laser elements can be reduced since the substantially (11-22) plane has a smaller piezoelectric field as compared with other semipolar planes.

In the aforementioned semiconductor laser device according to the first aspect, a third major surface of the substrate preferably has a surface orientation substantially identical to the non-C plane. According to this structure, the blue and green semiconductor laser elements including the first and second active layers having the first and second major surfaces of the non-C planes, respectively, can be easily formed by simply growing semiconductor layers on the substrate having the third major surface of the surface orientation of the non-C plane substantially identically to the first and second active layers of the blue and green semiconductor laser elements.

In the aforementioned semiconductor laser device according to the first aspect, the substrate is preferably made of a nitride-based semiconductor. According to this structure, the blue and green semiconductor laser elements including the first and second active layers made of the nitride-based semiconductors can be easily formed by simply growing semiconductor layers on the substrate made of the nitride-based semiconductor.

In this case, the first well layer is preferably made of InGaN having a first major surface of the non-C plane, the second well layer is preferably made of InGaN having a second major surface of the non-C plane, and the substrate is preferably made of GaN having a third major surface of the non-C plane. According to this structure, the blue and green semiconductor laser elements including the first and second active layers of InGaN having first and second major surfaces of semipolar planes, respectively, can be easily formed by simply growing semiconductor layers on the substrate of GaN having a third major surface of a semipolar plane identically to the first and second active layers of the blue and green semiconductor laser elements.

In the aforementioned semiconductor laser device provided with the first well layer having the thickness larger than that of the second well layer, a thickness of the first well layer is preferably at least about 6 nm and not more than about 15 nm, and a thickness of the second well layer is preferably less than about 6 nm. According to this structure, formation of crystal defects can be more reliably suppressed in the first and second well layers of the blue and green semiconductor laser elements.

In this case, the first well layer is preferably made of a nitride-based semiconductor containing In, and an In composition in the first well layer is preferably not more than about 20%. According to this structure, formation of crystal defects can be more reliably suppressed in the first well layer of the blue semiconductor laser element.

In the aforementioned semiconductor laser device provided with the first well layer having an In composition of not more than about 20%, the second well layer is preferably made of a nitride-based semiconductor containing In, and the In composition in the second well layer is preferably larger than about 20%. According to this structure, the thickness of the second well layer of the green semiconductor laser element easily causing crystal defects due to the In composition larger than about 20% can be reduced below that of the first well layer of the blue semiconductor laser element, whereby formation of crystal defects can be reliably suppressed in the second well layer of the green semiconductor laser element.

In the aforementioned semiconductor laser device provided with the first well layer having the thickness larger than that of the second well layer, the second active layer preferably has a single quantum well structure. According to this structure, the second active layer having the single quantum well structure can be inhibited from falling into a nonlayered structure due to excessive reduction of the thickness thereof, as compared with a case where the second active layer has a multiple quantum well structure.

In the aforementioned semiconductor laser device according to the first aspect, the blue semiconductor laser element preferably further includes a first light guide layer containing In formed on at least either a side of one surface or a side of another surface of the first active layer, the green semiconductor laser element preferably further includes a second light guide layer containing In formed on at least either a side of one surface or a side of another surface of the second active layer, and an In composition in the second light guide layer is preferably larger than an In composition in the first light guide layer. According to this structure, the second light guide layer can more confine light in the second active layer than the first light guide layer, whereby a green beam emitted from the green semiconductor laser element can be more confined in the second active layer. Thus, the green semiconductor laser element inferior in luminous efficiency as compared with the blue semiconductor laser element can ensure light confinement to an extent similar to that of the blue semiconductor laser element.

In the aforementioned semiconductor laser device according to the first aspect, the blue semiconductor laser element preferably further includes a first carrier blocking layer containing Al formed on at least either a side of one surface or a side of another surface of the first active layer, the green semiconductor laser element preferably further includes a second carrier blocking layer containing Al formed on at least either a side of one surface or a side of another surface of the second active layer, and an Al composition in the second carrier blocking layer is preferably larger than an Al composition in the first carrier blocking layer. According to this structure, the second carrier blocking layer can more confine light in the second active layer than the first carrier blocking layer, whereby the green beam emitted from the green semiconductor laser element can be more confined in the second active layer. Thus, the green semiconductor laser element inferior in luminous efficiency as compared with the blue semiconductor laser element can ensure light confinement to an extent similar to that of the blue semiconductor laser element.

In the aforementioned semiconductor laser device according to the first aspect, the blue semiconductor laser element preferably further includes a first cladding layer containing Al formed on at least either a side of one surface or a side of another surface of the first active layer, the green semiconductor laser element preferably further includes a second cladding layer containing Al formed on at least either a side of one surface or a side of another surface of the second active layer, and an Al composition in the second cladding layer is preferably larger than an Al composition in the first cladding layer. According to this structure, the second cladding layer can more confine light in the second active layer than the first cladding layer, whereby the green beam emitted from the green semiconductor laser element can be more confined in the second active layer. Thus, the green semiconductor laser element inferior in luminous efficiency as compared with the blue semiconductor laser element can ensure light confinement to an extent similar to that of the blue semiconductor laser element.

The aforementioned semiconductor laser device according to the first aspect preferably further includes a red semiconductor laser element bonded to at least any of the blue semiconductor laser element, the green semiconductor laser element and the substrate. The term “red semiconductor laser element” denotes a semiconductor laser element having an oscillation wavelength in the range of about 610 nm to about 750 nm. According to this structure, an RGB triple-wavelength semiconductor laser device including a blue/green double-wavelength semiconductor laser element portion including the blue and green semiconductor laser elements capable of suppressing reduction of the yield and the red semiconductor laser element can be obtained.

In this case, the red semiconductor laser element is preferably bonded to the substrate in a junction-down manner. According to this structure, heat generated in an active layer of the red semiconductor laser element can be radiated on the substrate, whereby an RGB triple-wavelength semiconductor laser device having a higher luminous efficiency can be prepared.

In the aforementioned semiconductor laser device according to the first aspect, the blue semiconductor laser element and the green semiconductor laser element preferably further include light guides extending in directions projecting [0001] directions on the major surfaces. In order to maximize optical gains of the semiconductor laser elements, the light guides must be formed perpendicularly to main directions of polarization of emission from the active layers. In other words, the optical gains of the blue and green semiconductor laser elements can be maximized while a blue beam of the blue semiconductor laser element and the green beam of the green semiconductor laser element can be emitted from a common cavity facet by forming the light guides in the directions projecting the [0001] directions on the major surfaces of the non-C planes.

In the aforementioned semiconductor laser device according to the first aspect, the first major surface is a semipolar plane in the non-C plane, and the second major surface is the semipolar plane. According to this structure, the first and second active layers can be inhibited from difficulty in crystal growth due to the major surfaces of the semipolar planes dissimilarly to a case where the same have major surfaces of non-polar planes included in non-C planes, whereby the first and second active layers can be inhibited from increase in the numbers of crystal defects.

In this case, the semipolar plane is preferably a plane inclined toward a (0001) plane or a (000-1) plane by at least about 10° and not more than about 70°. According to this structure, the optical gains of the blue and green semiconductor laser elements including the first and second active layers having the first and second major surfaces of the semipolar planes, respectively, can be more increased.

A display according to a second aspect of the present invention includes a semiconductor laser device including a substrate, a blue semiconductor laser element, formed on a surface of the substrate, including a first active layer made of a nitride-based semiconductor and having a first major surface of a non-C plane and a green semiconductor laser element, formed on a surface of the substrate, including a second active layer made of a nitride-based semiconductor and having a second major surface of a surface orientation substantially identical to the non-C plane, and means for modulating light emitted from the semiconductor laser device.

In the display according to the second aspect of the present invention, as hereinabove described, the first and second active layers, made of the nitride-based semiconductors, of the blue and green semiconductor laser elements formed on a surface of the same substrate have the first and second major surfaces of non-C planes of substantially identical surface orientations, respectively, whereby piezoelectric fields generated in the first and second active layers can be reduced as compared with a case where the first and second active layers have the first and second major surfaces of c-planes which are polar planes, respectively. Thus, inclinations of energy bands in the first and second well layers of the first and second active layers resulting from the piezoelectric fields can be reduced, whereby the quantities of changes (widths of fluctuations) in oscillation wavelengths of the blue and green semiconductor laser elements can be more reduced. Consequently, the display can display a desired image by employing the integrated semiconductor laser device, including the blue and green semiconductor laser elements formed on the surface of the same substrate, capable of suppressing reduction of the yield and modulating light with the means for modulating light.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view showing the structure of a semiconductor laser device according to a first embodiment of the present invention;

FIG. 2 is an enlarged sectional view showing the structure of an active layer of a blue semiconductor laser element of the semiconductor laser device according to the first embodiment shown in FIG. 1;

FIG. 3 is an enlarged sectional view showing the structure of an active layer of a green semiconductor laser element of the semiconductor laser device according to the first embodiment shown in FIG. 1;

FIGS. 4 to 6 are diagrams for illustrating a process for manufacturing the semiconductor laser device according to the first embodiment shown in FIG. 1;

FIG. 7 is a sectional view showing the structure of a semiconductor laser device according to a second embodiment of the present invention;

FIG. 8 is a schematic diagram showing a projector including the semiconductor laser device according to the second embodiment shown in FIG. 7 and cyclically turning on semiconductor laser elements in a time-series manner;

FIG. 9 is a timing chart showing a state where a control portion of the projector according to the second embodiment shown in FIG. 8 transmits signals in a time-series manner; and

FIG. 10 is a schematic diagram showing another projector including the semiconductor laser device according to the second embodiment shown in FIG. 7 and substantially simultaneously turning on the semiconductor laser elements.

### DESCRIPTION OF THE PREFERRED EMBODIMENTS

### First Embodiment

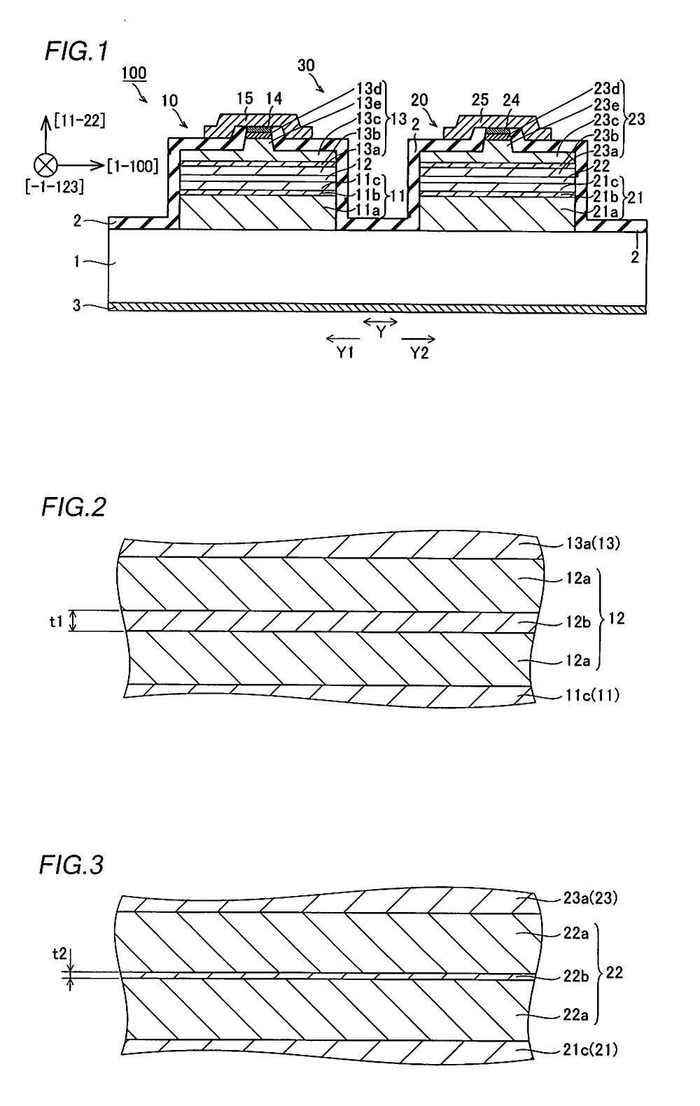

The structure of a semiconductor laser device 100 according to a first embodiment of the present invention is now described with reference to FIGS. 1 to 3.

In the semiconductor laser device 100 according to the first embodiment, a monolithic blue/green double-wavelength semiconductor laser element portion 30 consisting of a blue semiconductor laser element 10 having an oscillation wavelength of about 450 nm and a green semiconductor laser element 20 having an oscillation wavelength of about 530 nm is formed on an n-type GaN substrate 1 having a thickness of about 100 μm, as shown in FIG. 1. The blue semiconductor laser element 10 may be formed to have an oscillation wavelength in the range of about 435 nm to about 485 nm. The green semiconductor laser element 20 may be formed to have an oscillation wavelength in the range of about 500 nm to about 565 nm. The n-type GaN substrate 1 is an example of the “substrate” in the present invention.

The monolithic blue/green double-wavelength semiconductor laser element portion 30 is formed on the n-type GaN substrate 1 having a major surface of a (11-22) plane. The (11-22) plane is a semipolar plane inclined from a c-plane ((0001) plane) toward a [11-20] direction by about 58°.

The blue semiconductor laser element 10 has a structure obtained by stacking an n-type semiconductor layer 11, an active layer 12 and a p-type semiconductor layer 13 in this order on a region of the upper surface of the n-type GaN substrate 1 on the side of a [-1100] direction (direction Y1). The green semiconductor laser element 20 has a structure obtained by stacking an n-type semiconductor layer 21, an active layer 22 and a p-type semiconductor layer 23 in this order on a region of the upper surface of the same n-type GaN substrate 1 as the blue semiconductor laser element 10 on the side of a [1-100] direction (direction Y2). The active layers 12 and 22 are examples of the “first active layer” and the “second active layer” in the present invention, respectively.

The n-type semiconductor layer 11 of the blue semiconductor laser element 10 has an n-type cladding layer 11a of Si-doped n-type Al_{0.07}Ga_{0.93}N having a thickness of about 2 μm formed on the upper surface of the n-type GaN substrate 1, an n-type carrier blocking layer 11b of Si-doped n-type Al_{0.16}Ga_{0.84}N having a thickness of about 5 nm formed on the n-type cladding layer 11a and an n-type light guide layer 11c of Si-doped n-type In_{0.02}Ga_{0.98}N having a thickness of about 100 nm formed on the n-type carrier blocking layer 11b. The n-type cladding layer 11a is an example of the “second cladding layer” in the present invention, and the n-type carrier blocking layer 11b is an example of the “second carrier blocking layer” in the present invention. The n-type light guide layer 11c is an example of the “second light guide layer” in the present invention.

As shown in FIG. 2, the active layer 12 is made of InGaN having a major surface of a (11-22) plane identically to the n-type GaN substrate 1, and has a single quantum well (SQW) structure. More specifically, the active layer 12 has an SQW structure consisting of two barrier layers 12a of undoped In_{0.02}Ga_{0.98}N each having a thickness of about 20 nm formed on the upper surface of the n-type semiconductor layer 11 and a well layer 12b of undoped In_{0.20}Ga_{0.80}N having a thickness t1 of about 8 nm arranged between the two barrier layers 12a. The in-plane lattice constant of the well layer 12b is larger than that of the n-type GaN substrate 1, and hence a compressive strain is applied to the well layer 12b in the in-plane direction. The thickness t1 of the well layer 12b is preferably at least about 6 nm and not more than about 15 nm. According to the first embodiment, the well layer 12b can be inhibited from difficulty in crystal growth due to the major surface of the active layer 12 of the (11-22) plane dissimilarly to a case where the active layer 12 has a major surface of a non-polar plane such as an m-plane ((1-100) plane) or an a-plane ((11-20) plane), whereby the active layer 12 can be inhibited from increase in the number of crystal defects resulting from a large In composition. The active layer 12 may alternatively have a multiple quantum well (MQW) structure or the like. InGaN is an example of the “nitride-based semiconductor” in the present invention, and the well layer 12b is an example of the “first well layer” in the present invention.

As shown in FIG. 1, the p-type semiconductor layer 13 has a p-type light guide layer 13a of Mg-doped p-type In_{0.02}Ga_{0.98}N having a thickness of about 100 nm formed on the upper surface of the active layer 12, a p-type carrier blocking layer 13b of Mg-doped p-type Al_{0.16}Ga_{0.84}N having a thickness of about 20 nm formed on the p-type light guide layer 13a, a p-type cladding layer 13c of Mg-doped p-type Al_{0.07}Ga_{0.93}N having a thickness of about 700 nm formed on the p-type carrier blocking layer 13b and a p-type contact layer 13d of Mg-doped p-type In_{0.02}Ga_{0.98}N having a thickness of about 10 nm formed on the p-type cladding layer 13c. The p-type light guide layer 13a is an example of the “second light guide layer” in the present invention. The p-type carrier blocking layer 13b is an example of the “second carrier blocking layer” in the present invention, and the p-type cladding layer 13c is an example of the “second cladding layer” in the present invention.

The p-type cladding layer 13c and the p-type contact layer 13d constitute a striped ridge portion 13e formed on a substantially central portion of the blue semiconductor laser element 10 in a direction Y (directions Y1 and Y2), while the p-type cladding layer 13c has planar portions extending on both sides (in the direction Y) of the ridge portion 13e. The ridge portion 13e constitutes a light guide. The ridge portion 13e is formed to extend along a cavity direction ([-1-123] direction).

A current blocking layer 2 which is an insulating film is formed to cover the upper surfaces of the planar portions of the p-type cladding layer 13c, the side surfaces of the ridge portion 13e and the side surfaces of the n-type semiconductor layer 11, the active layer 12, the p-type light guide layer 13a, the p-type carrier blocking layer 13b and the p-type cladding layer 13c while exposing the upper surface of the ridge portion 13e. The current blocking layer 2 is made of SiO₂, and has a thickness of about 250 nm. The current blocking layer 2 is formed to further cover a prescribed region (region exposed from the blue semiconductor laser element 10 and the green semiconductor laser element 20) of the upper surface of the n-type GaN substrate 1, the upper surfaces of planar portions of a p-type cladding layer 23c, described later, of the green semiconductor laser element 20, the side surfaces of a ridge portion 23e described later and partial side surfaces of the n-type semiconductor layer 21, the active layer 22 and the p-type semiconductor layer 23 while exposing the upper surface of the ridge portion 23e. A p-side ohmic electrode 14 having a structure obtained by stacking a Pt layer having a thickness of about 5 nm, a Pd layer having a thickness of about 100 nm and an Au layer having a thickness of about 150 nm successively from the side closer to the p-type contact layer 13d is formed on the upper surface of the p-type contact layer 13d. A p-side pad electrode 15 having a structure obtained by stacking a Ti layer having a thickness of about 100 nm, a Pd layer having a thickness of about 100 nm and an Au layer having a thickness of about 3 μm successively from the side closer to the p-side ohmic electrode 14 is formed on a prescribed region (region located on the planar portions of the p-type cladding layer 13c and the side surfaces of the ridge portion 13e) of the current blocking layer 2 and the upper surface of the p-side ohmic electrode 14, to be electrically connected with the p-side ohmic electrode 14.

The green semiconductor laser element 20 has a structure similar to that of the blue semiconductor laser element 10, except for a well layer 22b, described later, of the active layer 22 described later. More specifically, the n-type semiconductor layer 21 of the green semiconductor laser element 20 has an n-type cladding layer 21a of Si-doped n-type Al_{0.10}Ga_{0.90}N having a thickness of about 2 μl m formed on the upper surface of the n-type GaN substrate 1, an n-type carrier blocking layer 21b of Si-doped n-type Al_{0.20}Ga_{0.80}N having a thickness of about 5 nm formed on the n-type cladding layer 21a and an n-type light guide layer 21c of Si-doped n-type In_{0.05}Ga_{0.95}N having a thickness of about 100 nm formed on the n-type carrier blocking layer 21b. The n-type cladding layer 21a is an example of the “first cladding layer” in the present invention, and the n-type carrier blocking layer 21b is an example of the “first carrier blocking layer” in the present invention. The n-type light guide layer 21c is an example of the “first light guide layer” in the present invention.

As shown in FIG. 3, the active layer 22 is made of InGaN having a major surface of a (11-22) plane identically to the n-type GaN substrate 1, and has an SQW structure. More specifically, the active layer 22 has an SQW structure consisting of two barrier layers 22a of undoped In_{0.02}Ga_{0.98}1N each having a thickness of about 20 nm formed on the upper surface of the n-type semiconductor layer 21 and the well layer 22b of undoped In_{0.33}Ga_{0.67}N having a thickness t2 of about 2.5 nm arranged between the two barrier layers 22a. The in-plane lattice constant of the well layer 22b is larger than that of the n-type GaN substrate 1, and hence a compressive strain is applied to the well layer 22b in the in-plane direction. The compressive strain of the well layer 22b of the green semiconductor laser element 20 is larger than that of the well layer 12b of the blue semiconductor laser element 10. The thickness t2 of the well layer 22b is preferably less than about 6 nm. The thickness t2 of the well layer 22b of the active layer 22 is so sufficiently small that the well layer 22b can maintain a layered structure due to the SQW structure of the active layer 22, as compared with a case where the active layer 22 has an MQW structure. The well layer 22b is an example of the “second well layer” in the present invention.

The thickness t1 (about 8 nm) of the well layer 12b, having the In composition of about 20%, of the active layer 12 of the blue semiconductor laser element 10 shown in FIG. 2 is rendered larger than the thickness t2 (about 2.5 nm) of the well layer 22b, having the In composition of about 33%, of the active layer 22 of the green semiconductor laser element 20 shown in FIG. 3. According to the first embodiment, the thickness of the well layer in each active layer is preferably not more than 10 nm in order to suppress formation of crystal defects when the In composition is about 20%, while the thickness of the well layer is preferably not more than about 3 nm in order to suppress formation of crystal defects when the In composition is about 30%. If the active layer 22 has an MQW structure, the total thickness of well layers in the active layer 22 is preferably within the aforementioned range.

As shown in FIG. 1, the p-type semiconductor layer 23 has a p-type light guide layer 23a of Mg-doped p-type In_{0.05}Ga_{0.95}N having a thickness of about 100 nm formed on the upper surface of the active layer 22, a p-type carrier blocking layer 23b of Mg-doped p-type Al_{0.20}Ga_{0.80}N having a thickness of about 20 nm formed on the p-type light guide layer 23a, the p-type cladding layer 23c of Mg-doped p-type Al_{0.10}Ga_{0.90}N having a thickness of about 700 nm formed on the p-type carrier blocking layer 23b and a p-type contact layer 23d of Mg-doped p-type In_{0.02}Ga_{0.98}N having a thickness of about 10 nm formed on the p-type cladding layer 23c. The p-type light guide layer 23a is an example of the “first light guide layer” in the present invention. The p-type carrier blocking layer 23b is an example of the “first carrier blocking layer” in the present invention, and the p-type cladding layer 23c is an example of the “first cladding layer” in the present invention.

The p-type cladding layer 23c and the p-type contact layer 23d constitute the striped ridge portion 23e formed on a substantially central portion of the green semiconductor laser element 20 in the direction Y, while the p-type cladding layer 23c has the planar portions extending on both sides (in the direction Y) of the ridge portion 23e. The ridge portion 23e constitutes a light guide. The ridge portion 23e is formed to extend along the cavity direction ([-1-123] direction).

The Al compositions (about 10%) in the n- and p-type cladding layers 21a and 23c of the green semiconductor laser element 20 are rendered larger than the Al compositions (about 7%) in the n- and p-type cladding layers 11a and 13c of the blue semiconductor laser element 10. The Al compositions (about 20%) in the n- and p-type carrier blocking layers 21b and 23b of the green semiconductor laser element 20 are rendered larger than the Al compositions (about 16%) in the n- and p-type carrier blocking layers 11b and 13b of the blue semiconductor laser element 10. The In compositions (about 5%) in the n- and p-type light guide layers 21c and 23a of the green semiconductor laser element 20 are rendered larger than the In compositions (about 2%) in the n- and p-type light guide layers 11c and 13a of the blue semiconductor laser element 10. Thus, the green beam hard to confine by wavelength dispersion of a refractive index can be confined between the cladding layers 21a and 23c and the carrier blocking layers 21b and 23b and the light guide layers 21c and 23a to an extent similar to that of a blue beam, whereby the green semiconductor laser element 20 can ensure light confinement to an extent similar to that of the blue semiconductor laser element 10.

The Al compositions in the n-type cladding layer 21a, the n-type carrier blocking layer 21b, the p-type carrier blocking layer 23b and the p-type cladding layer 23c of the green semiconductor laser element 20 are preferably larger than those in the n-type cladding layer 11a, the n-type carrier blocking layer 11b, the p-type carrier blocking layer 13b and the p-type cladding layer 13c of the blue semiconductor laser element 10, respectively. On the other hand, cracking and warpage resulting from different lattice constants of crystal lattices of AlGaN and the n-type GaN substrate 1 can be reduced by reducing the Al compositions in the blue and green semiconductor laser elements 10 and 20, although the light confinement functions are reduced in this case.

The In compositions in the n- and p-type light guide layers 21c and 23a of the green semiconductor laser element 20 are preferably larger than those in the n- and p-type light guide layers 11c and 13a of the blue semiconductor laser element 10.

A p-side ohmic electrode 24 similar to the p-side ohmic electrode 14 of the blue semiconductor laser element 10 is formed on the upper surface of the p-type contact layer 23d. A p-side pad electrode 25 similar to the p-side pad electrode 15 of the blue semiconductor laser element 10 is formed on a prescribed region (region located on the planar portions of the p-type cladding layer 23c and the side surfaces of the ridge portion 23e) of the current blocking layer 2 and the upper surface of the p-side ohmic electrode 24, to be separated from the p-side pad electrode 15 of the blue semiconductor laser element 10.

An n-side electrode 3 consisting of an Al layer having a thickness of about 10 nm, a Pt layer having a thickness of about 20 nm and an Au layer having a thickness of about 300 nm successively from the side closer to the n-type GaN substrate 1 is formed on the lower surface of the n-type GaN substrate 1.

A process for manufacturing the semiconductor laser device 100 is now described with reference to FIGS. 1 and 4 to 6.

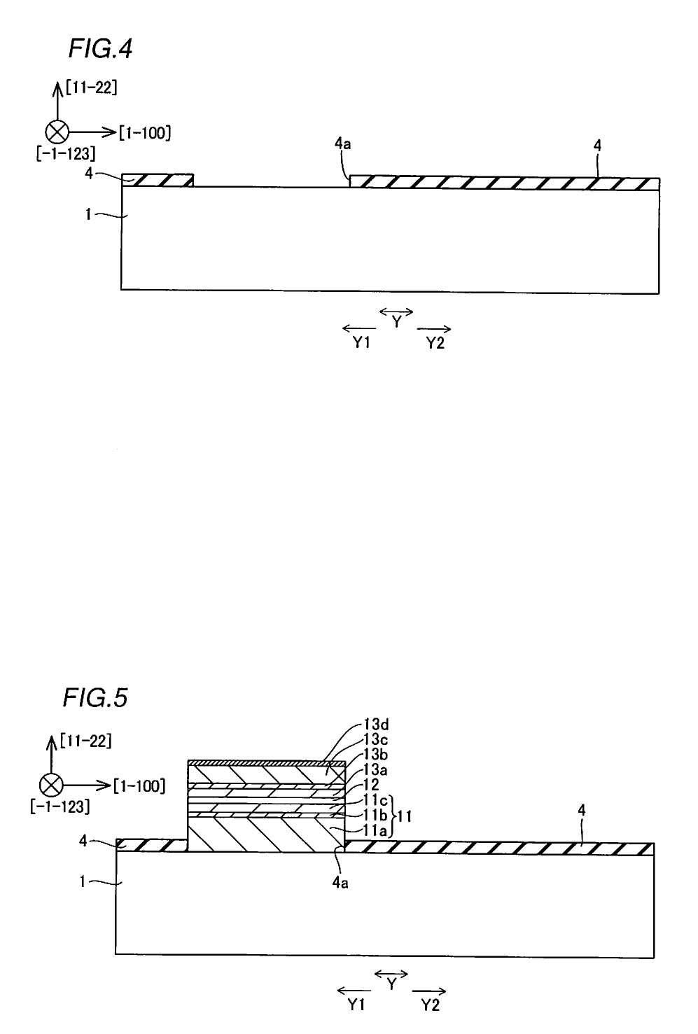

As shown in FIG. 4, a mask layer 4 of SiO₂ having a thickness of about 500 nm is formed on the region of the upper surface of the n-type GaN substrate 1, having the major surface of the (11-22) plane, on the side of the [-1100] direction (direction Y1).

As shown in FIG. 5, the n-type semiconductor layer 11, the active layer 12 and the p-type semiconductor layer 13 not yet provided with the ridge portion 13e are selectively grown in this order by metal-organic chemical vapor deposition (MOCVD) on a portion of the upper surface of the n-type GaN substrate 1 exposed in an opening 4a of the mask layer 4.

Thereafter the mask layer 4 is removed. Then, a mask layer 5 of SiO₂ having a thickness of about 500 nm is formed on the upper surfaces of the n-type GaN substrate 1 and the p-type semiconductor layer 13 and the side surfaces of the n-type semiconductor layer 11, the active layer 12 and the p-type semiconductor layer 13.

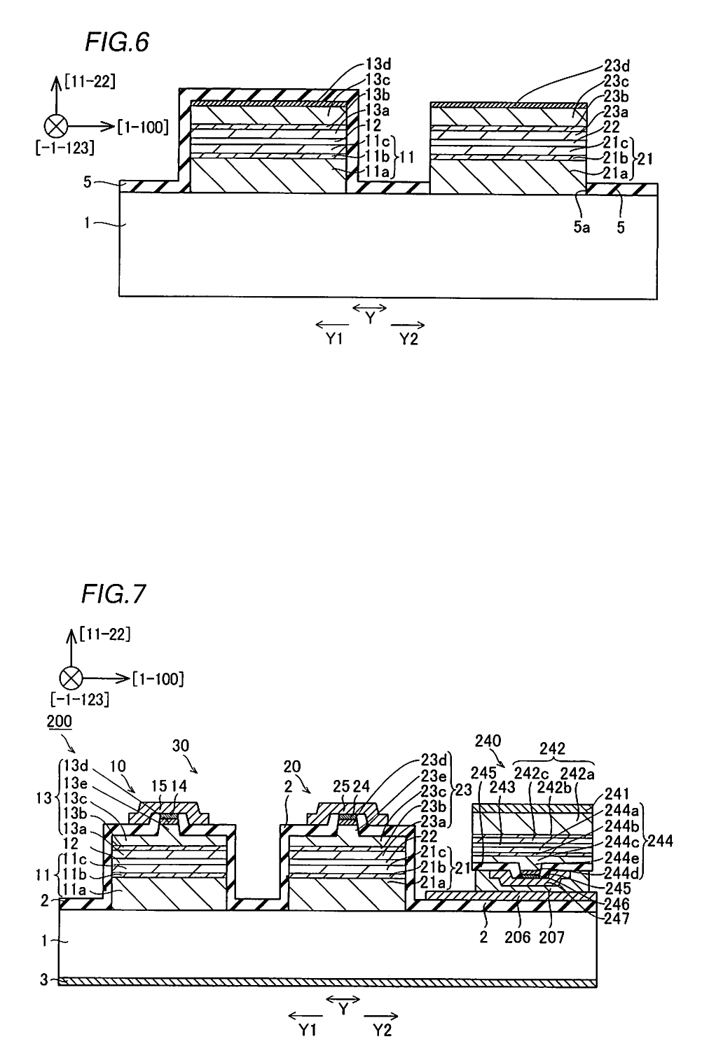

Then, a portion of the mask layer 5 located on the region of the upper surface of the n-type GaN substrate 1 on the side of the [1-100] direction (direction Y2) is removed thereby forming an opening 5a having a width of about 400 μm, as shown in FIG. 6. Thereafter the n-type semiconductor layer 21, the active layer 22 and the p-type semiconductor layer 23 not yet provided with the ridge portion 23e are selectively grown in this order by MOCVD on a portion of the upper surface of the n-type GaN substrate 1 exposed in the opening 5a from which the mask layer 5 is partially removed.

Thereafter the mask layer 5 is removed. Then, the ridge portions 13e and 23e are formed to extend along the cavity direction ([-1-123] direction). Consequently, the p-type semiconductor layers 13 and 23 are formed. Then, the current blocking layer 2 is formed. Then, portions of the current blocking layer 2 located on the upper surfaces of the p-type contact layers 13d and 23d are removed, to expose the p-type contact layers 13d and 23d. Thereafter the p-side ohmic electrodes 14 and 24 are formed on the upper surfaces of the p-type contact layers 13d and 23d by vacuum evaporation, respectively, and the p-side pad electrodes 15 and 25 are thereafter formed.

Thereafter the lower surface of the n-type GaN substrate 1 is polished so that the thickness of the n-type GaN substrate 1 is about 100 μm. Then, the n-side electrode 3 is formed on the lower surface of the n-type GaN substrate 1 by vacuum evaporation. Thus, the monolithic blue/green double-wavelength semiconductor laser element portion 30 is formed in a wafer state. Thereafter cavity facets perpendicular to the cavity direction ([-1-123] direction) are formed on prescribed positions by etching, and the wafer is divided. Thus, the individual monolithic blue/green double-wavelength semiconductor laser element portion 30 constituting the semiconductor laser device 100 is formed as shown in FIG. 1. The cavity facets may alternatively be formed by cleaving the prescribed positions of the wafer.

According to the first embodiment, as hereinabove described, the green semiconductor laser element 20 including the active layer 22 of InGaN having the major surface of the (11-22) plane is formed on the same n-type GaN substrate 1 as the blue semiconductor laser element 10 including the active layer 12 of InGaN having the major surface of the (11-22) plane so that piezoelectric fields generated in the active layers 12 and 22 can be reduced as compared with a case where the active layers 12 and 22 have major surfaces of c-planes ((0001) planes), whereby inclinations of energy bands in the well layers 12b and 22b of the active layers 12 and 22 resulting from the piezoelectric fields can be reduced. Thus, the quantities of changes (widths of fluctuations) in the oscillation wavelengths of the blue and green semiconductor laser elements 10 and 20 can be more reduced, whereby reduction of the yield of the semiconductor laser device 100 including the blue and green semiconductor laser elements 10 and 20 formed on the surface of the same n-type GaN substrate 1 can be suppressed. Further, the quantities of changes (widths of fluctuations) in the oscillation wavelengths of the blue and green semiconductor laser elements 10 and 20 with respect to the quantities of changes in carrier densities of the active layers 12 and 22 can be more reduced due to the small piezoelectric fields. Thus, difficulty in controlling tinges of the blue and green semiconductor laser elements 10 and 20 can be suppressed. In addition, luminous efficiencies of the blue and green semiconductor laser elements 10 and 20 can be improved due to the small piezoelectric fields.

According to the first embodiment, the quantities of changes in the oscillation wavelengths of the blue and green semiconductor laser elements 10 and 20 can be reduced since the (11-22) planes have smaller piezoelectric fields as compared with other semipolar planes. Further, the semiconductor layers (active layers 12 and 22) having the major surfaces of the (11-22) planes can be easily formed as compared with a case where the orientations of the major surfaces are non-polar planes such as m-planes ((1-100) planes) or a-planes ((11-20) planes) perpendicular to c-planes ((0001) planes).

According to the first embodiment, the active layer 12 of the blue semiconductor laser element 10 is made of InGaN having the major surface of the (11-22) plane identically to the n-type GaN substrate 1 while the active layer 22 of the green semiconductor laser element 20 is also made of InGaN having the major surface of the (11-22) plane identically to the n-type GaN substrate 1, whereby the blue and green semiconductor laser elements 10 and 20 including the active layers 12 and 22 of InGaN having the major surfaces of the (11-22) planes can be easily formed by simply growing semiconductor layers on the n-type GaN substrate 1 of GaN having the major surface of the (11-22) plane identically to the active layers 22 and 12 of the blue and green semiconductor laser elements 10 and 20.

According to the first embodiment, the thickness t1 (about 8 nm) of the well layer 12b, having the compressive strain, of the active layer 12 of the blue semiconductor laser element 10 is rendered larger than the thickness t2 (about 2.5 nm) of the well layer 22b, having the compressive strain, of the active layer 22 of the green semiconductor laser element 20, whereby formation of crystal defects can be suppressed in the well layer 22b easily causing crystal defects due to the large In composition.

According to the first embodiment, the well layer 12b of the active layer 12 of the blue semiconductor laser element 10 is made of InGaN having the In composition of not more than about 20% while the thickness t1 (about 8 nm) of the well layer 12b is set to at least about 6 nm and not more than about 15 nm, and the well layer 22b of the active layer 22 of the green semiconductor laser element 20 is made of InGaN having the In composition larger than about 20% while the thickness t2 (about 2.5 nm) of the well layer 22b is set to less than about 6 nm, whereby formation of crystal defects can be reliably suppressed in the well layers 12b and 22b of the blue and green semiconductor laser elements 10 and 20.

According to the first embodiment, the n-type GaN substrate 1 is formed to have the major surface of the (11-22) plane, whereby the blue and green semiconductor laser elements 10 and 20 including the active layers 12 and 22 having the major surfaces of the non-C planes can be easily formed by simply forming semiconductor layers on the n-type GaN substrate 1 having the major surface of the (11-22) plane identically to the active layers 12 and 22 of the blue and green semiconductor laser elements 10 and 20.

According to the first embodiment, the active layer 22 having the SQW structure can be inhibited from falling into a nonlayered structure due to excessive reduction of the thickness t2 of the well layer 22b of the active layer 22, as compared with a case where the active layer 22 has an MQW structure.

According to the first embodiment, the In compositions (about 5%) in the n- and p-type light guide layers 21c and 23a of the green semiconductor laser element 20 are rendered larger than the In compositions (about 2%) in the n- and p-type light guide layers 11c and 13a of the blue semiconductor laser element 10 so that the n- and p-type light guide layers 21c and 23a can more confine light in the active layers (12 and 22) than the n- and p-type light guide layers 11c and 13a, whereby the green beam of the green semiconductor laser element 20 can be more confined in the active layer 22. Thus, the green semiconductor laser element 20 inferior in luminous efficiency as compared with the blue semiconductor laser element 10 can ensure light confinement to an extent similar to that of the blue semiconductor laser element 10.

According to the first embodiment, the Al compositions (about 20%) in the n- and p-type carrier blocking layers 21b and 23b of the green semiconductor laser element 20 are rendered larger than the Al compositions (about 16%) in the n- and p-type carrier blocking layers 11b and 13b of the blue semiconductor laser element 10 so that the n- and p-type carrier blocking layers 21b and 23b can more confine light in the active layers (12 and 22) than the n- and p-type carrier blocking layers 11b and 13b, whereby the green beam of the green semiconductor laser element 20 can be more confined in the active layer 22. Thus, the green semiconductor laser element 20 inferior in luminous efficiency as compared with the blue semiconductor laser element 10 can ensure light confinement to an extent similar to that of the blue semiconductor laser element 10.

According to the first embodiment, the Al compositions (about 10%) in the n- and p-type cladding layers 21a and 23c of the green semiconductor laser element 20 are rendered larger than the Al compositions (about 7%) in the n- and p-type cladding layers 11a and 13c of the blue semiconductor laser element 10 so that the n- and p-type cladding layers 21a and 23c can more confine light in the active layers (12 and 22) than the n- and p-type cladding layers 11a and 13c, whereby the green beam of the green semiconductor laser element 20 can be more confined in the active layer 22. Thus, the green semiconductor laser element 20 inferior in luminous efficiency as compared with the blue semiconductor laser element 10 can ensure light confinement to an extent similar to that of the blue semiconductor laser element 10.

According to the first embodiment, the blue and green semiconductor laser elements 10 and 20 are provided with the light guides extending in the directions ([-1-123] directions) projecting the [0001] directions on the (11-22) planes, whereby the optical gains of the blue and green semiconductor laser elements 10 and 20 can be maximized, while the blue beam of the blue semiconductor laser element 10 and the green beam of the green semiconductor laser element 20 can be emitted from common cavity facets.

According to the first embodiment, the active layers 12 and 22 have the major surfaces of the (11-22) planes so that difficulty in crystal growth can be suppressed in the active layer 12 and 22 due to the major surfaces of the (11-22) planes dissimilarly to the case where the orientations of the major surfaces are non-polar planes such as m-planes ((1-100) planes) or a-planes ((11-20) planes) included in the non-C planes, whereby the active layers 12 and 22 can be inhibited from increase in the numbers of crystal defects resulting from large In compositions.

According to the first embodiment, the semipolar (11-22) planes are inclined from the c-planes ((0001) planes) toward the [11-20] directions by about 58°, whereby the optical gains of the blue and green semiconductor laser elements 10 and 20 including the active layers 12 and 22 having the major surfaces of the (11-22) planes included in the semipolar planes can be more increased.

### Second Embodiment

A semiconductor laser device 200 according to a second embodiment of the present invention is now described with reference to FIGS. 7 to 10. In the semiconductor laser device 200 according to the second embodiment, a red semiconductor laser element 240 is bonded onto an n-type GaN substrate 1 provided with a monolithic blue/green double-wavelength semiconductor laser element portion 30, dissimilarly to the aforementioned first embodiment. Projectors 250 and 260 each including the semiconductor laser device 200 are also described.

First, the structure of the semiconductor laser device 200 according to the second embodiment of the present invention is described with reference to FIG. 7.

In the semiconductor laser device 200 according to the second embodiment of the present invention, the red semiconductor laser element 240 having an oscillation wavelength of about 640 nm is bonded onto the upper surface of the n-type GaN substrate 1 on the side of a [1-100] direction (direction Y2), not provided with a blue semiconductor laser element 10 and a green semiconductor laser element 20, in a junction-down manner to direct a p-n junction portion downward, as shown in FIG. 7. The red semiconductor laser element 240 may be formed to have an oscillation wavelength in the range of about 610 nm to about 750 nm. More specifically, a p-side electrode 206 is formed on the upper surface of a current blocking layer 2, formed on the n-type GaN substrate 1, on the side of the direction Y2 at a prescribed interval from the green semiconductor laser element 20. The p-side electrode 206 is provided to be wire-bondable with a wire (not shown). The red semiconductor laser element 240 is bonded onto the upper surface of the p-side electrode 206 with a fusion layer 207 made of conductive solder or the like.

The red semiconductor laser element 240 has a structure obtained by stacking an n-type semiconductor layer 242, an active layer 243 and a p-type semiconductor layer 244 in this order on the lower surface of an n-side electrode 241 formed by stacking an AuGe layer, an Ni layer and an Au layer in this order. The n-type semiconductor layer 242 has a structure obtained by stacking an n-type cladding layer 242a of Si-doped n-type AlGaInP, an n-type carrier blocking layer 242b of undoped AlGaInP and an n-type light guide layer 242c of undoped AlGaInP in this order on the lower surface of the n-side electrode 241.

The active layer 243 has an MQW structure obtained by alternately stacking two barrier layers of undoped AlGaInP and three well layers of undoped InGaP on the lower surface of the n-type semiconductor layer 242. The active layer 243 may alternatively have a single-layer structure or an SQW structure.

The p-type semiconductor layer 244 has a structure obtained by stacking a p-type light guide layer 244a of undoped AlGaInP, a p-type carrier blocking layer 244b of undoped AlGaInP, a p-type cladding layer 244c of Zn-doped p-type AlGaInP and a p-type contact layer 244d consisting of a multilayer structure of a Zn-doped p-type GaInP layer and a Zn-doped p-type GaAs layer in this order on the lower surface of the active layer 243. The p-type cladding layer 244c and the p-type contact layer 244d constitute a striped ridge portion 244e formed on a substantially central portion of the red semiconductor laser element 240 in a direction Y (directions Y1 and Y2), while the p-type cladding layer 244c has planar portions extending on both sides (in the direction Y) of the ridge portion 244e. The ridge portion 244e constitutes a light guide.

A current blocking layer 245 which is an insulating film is formed to cover the lower surfaces of the planar portions of the p-type cladding layer 244c and the side surfaces of the ridge portion 244e while exposing the lower surface of the ridge portion 244e. A p-side ohmic electrode 246 having a structure obtained by stacking a Cr layer and an Au layer in this order is formed on the lower surface of the p-type contact layer 244d. A p-side electrode 247 of Au or the like is formed on a prescribed region of the current blocking layer 245 and the lower surface of the p-side ohmic electrode 246, to be electrically connected with the p-side ohmic electrode 246. Prescribed regions of the p-side electrode 247 and the current blocking layer 245 are bonded to the p-side electrode 206 through the fusion layer 207. The remaining structure of the semiconductor laser device 200 according to the second embodiment is similar to that of the semiconductor laser device 100 according to the aforementioned first embodiment.

The projectors 250 and 260 each including the semiconductor laser device 200 according to the second embodiment of the present invention are described with reference to FIGS. 7 to 10.

First, the projector 250 turning on the semiconductor laser elements 10, 20 and 240 in a time-series manner is described with reference to FIGS. 7 to 9.

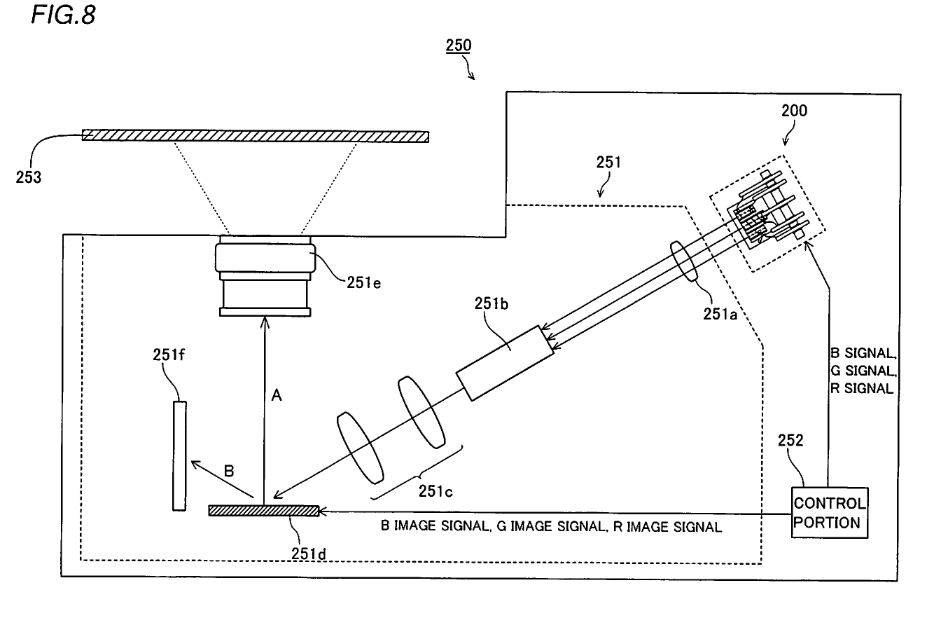

The projector 250 according to the second embodiment of the present invention is provided with the semiconductor laser device 200 including the blue semiconductor laser element 10 (see FIG. 7), the green semiconductor laser element 20 (see FIG. 7) and the red semiconductor laser element 240 (see FIG. 7), an optical system 251 consisting of a plurality of optical components and a control portion 252 controlling the semiconductor laser device 200 and the optical system 251, as shown in FIG. 8. Thus, the projector 250 is so formed that beams emitted from the semiconductor laser device 200 are modulated by the optical system 251 and thereafter projected on a screen 253 or the like.

In the optical system 251, the beams emitted from the semiconductor laser device 200 are converted to parallel beams by a lens 251a, and thereafter introduced into a light pipe 251b.

The light pipe 251b has a specular inner surface, and the beams are repeatedly reflected by the inner surface of the light pipe 251b to travel in the light pipe 251b. At this time, intensity distributions of the beams of respective colors emitted from the light pipe 251b are uniformized due to multiple reflection in the light pipe 251b. The beams emitted from the light pipe 251b are introduced into a digital micromirror device (DMD) 251d through a relay optical system 251c.

The DMD 251d consists of a group of small mirrors arranged in the form of a matrix. The DMD 251d has a function of expressing (modulating) the gradation of each pixel by switching the direction of reflection of light on each pixel position between a first direction A toward a projection lens 251e and a second direction B deviating from the projection lens 251e. Light (ON-light) incident upon each pixel position and reflected in the first direction A is introduced into the projection lens 251e and projected on a projected surface (screen 253). On the other hand, light (OFF-light) reflected by the DMD 251d in the second direction B is not introduced into the projection lens 251e but absorbed by a light absorber 251f.

In the projector 250, the control portion 252 is formed to supply a pulse voltage to the semiconductor laser device 200, thereby dividing the blue semiconductor laser element 10, the green semiconductor laser element 20 and the red semiconductor laser element 240 of the semiconductor laser device 200 in a time-series manner and cyclically driving the same one by one. Further, the control portion 252 is so formed that the DMD 251d of the optical system 251 modulates the gradations between the respective pixels in synchronization with the driving of the blue semiconductor laser element 10, the green semiconductor laser element 20 and the red semiconductor laser element 240.

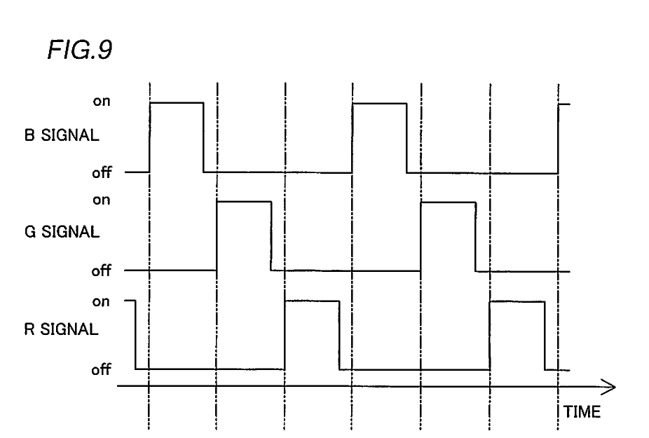

More specifically, a B signal related to the driving of the blue semiconductor laser element 10, a G signal related to the driving of the green semiconductor laser element 20 and an R signal related to the driving of the red semiconductor laser element 240 are divided in a time-series manner not to overlap with each other and supplied to the semiconductor laser device 200 by the control portion 252, as shown in FIG. 9. In synchronization with the B, G and R signals, the control portion 252 outputs a B image signal, a G image signal and an R image signal to the DMD 251d.

Thus, the blue semiconductor laser element 10 emits a blue beam on the basis of the B signal, while the DMD 251d modulates the blue beam at this timing on the basis of the B image signal. Further, the green semiconductor laser element 20 emits a green beam on the basis of the G signal output subsequently to the B signal, and the DMD 251d modulates the green beam at this timing on the basis of the G image signal. In addition, the red semiconductor laser element 240 emits a red beam on the basis of the R signal output subsequently to the G signal, and the DMD 251d modulates the red beam at this timing on the basis of the R image signal. Thereafter the blue semiconductor laser element 10 emits the blue beam on the basis of the B signal output subsequently to the R signal, and the DMD 251d modulates the blue beam again at this timing on the basis of the B image signal. The aforementioned operations are so repeated that an image formed by application of the laser beams based on the B, G and R image signals is projected on the projected surface (screen 253). The projector 250 cyclically turning on the semiconductor laser elements 10, 20 and 240 of the semiconductor laser device 200 according to the second embodiment of the present invention in a time-series manner is constituted in the aforementioned manner.

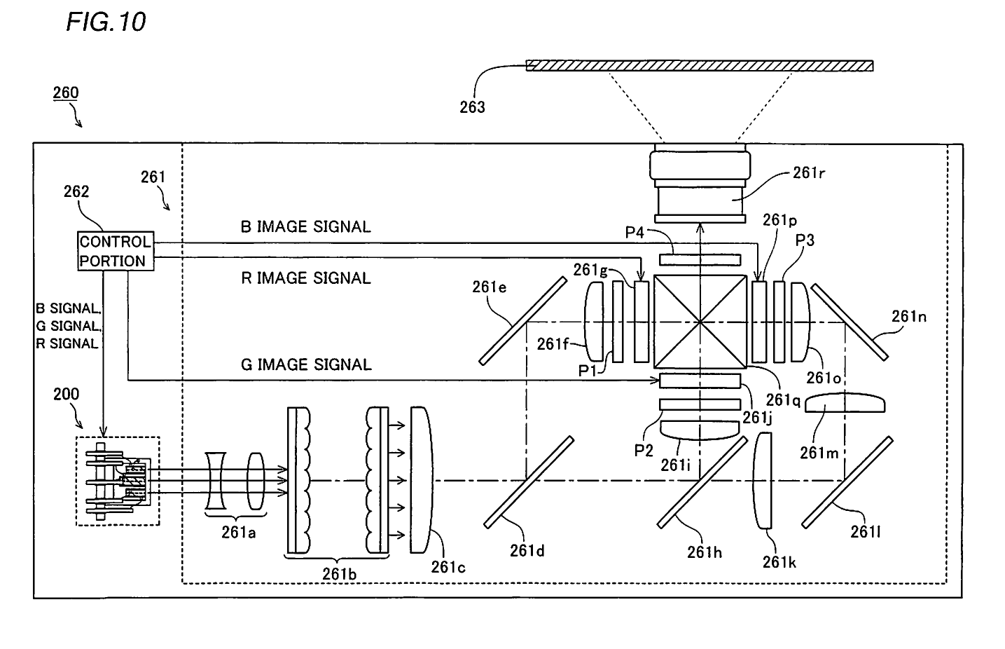

The projector 260 substantially simultaneously turning on the semiconductor laser elements 10, 20 and 240 is now described with reference to FIGS. 7 and 10.

The projector 260 according to the second embodiment of the present invention is provided with the semiconductor laser device 200 including the blue semiconductor laser element 10 (see FIG. 7), the green semiconductor laser element 20 (see FIG. 7) and the red semiconductor laser element 240 (see FIG. 7), an optical system 261 consisting of a plurality of optical components and a control portion 262 controlling the semiconductor laser device 200 and the optical system 261, as shown in FIG. 10. Thus, the projector 260 is so formed that laser beams emitted from the semiconductor laser device 200 are modulated by the optical system 261 and thereafter projected on an external screen 263 or the like.

In the optical system 261, the laser beams emitted from the semiconductor laser device 200 are converted to parallel beams having prescribed beam diameters by a dispersion angle control lens 261a consisting of a concave lens and a convex lens, and thereafter introduced into a fly-eye integrator 261b. The fly-eye integrator 261b is so formed that two fly-eye lenses consisting of fly-eye lens groups face each other, and provides a lens function to the beams introduced from the dispersion angle control lens 261a so that light quantity distributions in incidence upon liquid crystal panels 261g, 261j and 261p are uniform. In other words, the beams transmitted through the fly-eye integrator 261b are so adjusted that the same can be incident upon the liquid crystal panels 261g, 261j and 261p with spreads of aspect ratios (16:9, for example) corresponding to the sizes of the liquid crystal panels 261g, 261j and 261p.

The beams transmitted through the fly-eye integrator 261b are condensed by a condenser lens 261c. In the beams transmitted through the condenser lens 261c, only the red beam is reflected by a dichroic mirror 261d, while the blue and green beams are transmitted through the dichroic mirror 261d.

The red beam is parallelized by a lens 261f through a mirror 261e, and thereafter incident upon the liquid crystal panel 261g. The liquid crystal panel 261g is driven in response to a red driving signal (R image signal), thereby modulating the red beam. The red beam transmitted through the lens 261f is incident upon the liquid crystal panel 261g through an incidence-side polarizing plate P1.

In the beams transmitted through the dichroic mirror 261d, only the green beam is reflected by a dichroic mirror 261h, while the blue beam is transmitted through the dichroic mirror 261h.

The green beam is parallelized by a lens 261i, and thereafter incident upon the liquid crystal panel 261j. The liquid crystal panel 261j is driven in response to a green driving signal (G image signal), thereby modulating the green beam. The green beam transmitted through the lens 261i is incident upon the liquid crystal panel 261j through an incidence-side polarizing plate P2.

The blue beam transmitted through the dichroic mirror 261h passes through a lens 261k, a mirror 261l, a lens 261m and a mirror 261n, is parallelized by a lens 261o, and thereafter incident upon the liquid crystal panel 261p. The liquid crystal panel 261p is driven in response to a blue driving signal (B image signal), thereby modulating the blue beam. The blue beam transmitted through the lens 261o is incident upon the liquid crystal panel 261p through an incidence-side polarizing plate P3.

Thereafter the red, green and blue beams modulated by the liquid crystal panels 261g, 261j and 261p are synthesized by a dichroic prism 261q, and thereafter introduced into a projection lens 261r through an emission-side polarizing plate P4. The projection lens 261r stores a lens group for imaging projected light on a projected surface (screen 263) and an actuator for adjusting the zoom and the focus of the projected image by partially displacing the lens group in an optical axis direction.

In the projector 260, the control portion 262 supplies stationary voltages as a B signal related to driving of the blue semiconductor laser element 10, a G signal related to driving of the green semiconductor laser element 20 and an R signal related to driving of the red semiconductor laser element 240 to the semiconductor laser elements 10, 20 and 240 of the semiconductor laser device 200, respectively. Thus, the blue semiconductor laser element 10, the green semiconductor laser element 20 and the red semiconductor laser element 240 of the semiconductor laser device 200 are substantially simultaneously oscillated. The control portion 262 is formed to control the intensities of the beams emitted from the blue semiconductor laser element 10, the green semiconductor laser element 20 and the red semiconductor laser element 240 of the semiconductor laser device 200, thereby controlling the hue, brightness etc. of pixels projected on the screen 263. Thus, the control portion 262 projects a desired image on the screen 263. The projector 260 substantially simultaneously turning on the semiconductor laser elements 10, 20 and 240 of the semiconductor laser device 200 according to the second embodiment of the present invention is constituted in the aforementioned manner.

According to the second embodiment, as hereinabove described, the RBG triple-wavelength semiconductor laser device 200, including the blue/green double-wavelength semiconductor laser element portion 30 including the blue and green semiconductor laser elements 10 and 20 capable of suppressing reduction of the yield and the red semiconductor laser element 240 can be obtained due to the provision of the red semiconductor laser element 240 bonded onto the n-type GaN substrate 1.

According to the second embodiment, the red semiconductor laser element 240 is bonded onto the upper surface of the n-type GaN substrate 1 in the direction Y2 in the junction-down manner to direct the p-n junction portion downward so that heat generated in the active layer 243 of the red semiconductor laser element 240 can be radiated on the n-type GaN substrate 1, whereby the RGB triple-wavelength semiconductor laser device 200 including the red semiconductor laser element 240 having a higher luminous efficiency can be prepared.

According to the second embodiment, the projector 250 is so formed that the control portion 252 supplies the pulse voltage to the semiconductor laser device 200 thereby dividing the blue semiconductor laser element 10, the green semiconductor laser element 20 and the red semiconductor laser element 240 of the semiconductor laser device 200 in a time-series manner and cyclically driving the same one by one. According to this structure, piezoelectric fields in the active layers 12 and 22 of the blue and green semiconductor laser elements 10 and 20 can be reduced also when the tinges of the blue and green semiconductor laser elements 10 and 20 divided in a time-series manner and cyclically driven one by one are hard to control. Thus, the quantities of changes (widths of fluctuations) in the oscillation wavelengths of the blue and green semiconductor laser elements 10 and 20 with respect to the quantities of changes in carrier densities of the active layers 12 and 22 can be more reduced, whereby difficulty in controlling the tinges of the blue and green semiconductor laser elements 10 and 20 can be suppressed.

According to the second embodiment, the projector 260 is so formed that the control portion 262 supplies the stationary voltages to the semiconductor laser device 200 thereby substantially simultaneously oscillating the blue semiconductor laser element 10, the green semiconductor laser element 20 and the red semiconductor laser element 240 of the semiconductor laser device 200. According to this structure, piezoelectric fields in the active layers 12 and 22 of the blue and green semiconductor laser elements 10 and 20 can be reduced also when power consumption is increased in the semiconductor laser device 200 whose semiconductor laser elements 10, 20 and 240 are substantially simultaneously oscillated. Thus, the luminous efficiencies of the blue and green semiconductor laser elements 10 and 20 can be improved, whereby the semiconductor laser device 200 can be inhibited from increase in the power consumption.

According to the second embodiment, the projector 250 is provided with the semiconductor laser device 200 and the optical system 251 while the projector 260 is provided with the semiconductor laser device 200 and the optical system 261, whereby a desired image can be displayed by employing the semiconductor laser device 200, including the blue and green semiconductor laser elements 10 and 20 formed on the surface of the same n-type GaN substrate 1, capable of suppressing reduction of the yield and modulating the beams with the optical system 251 and 261. The remaining effects of the second embodiment are similar to those of the aforementioned first embodiment.

Although the present invention has been described and illustrated in detail, it is clearly understood that the same is by way of illustration and example only and is not to be taken by way of limitation, the spirit and scope of the present invention being limited only by the terms of the appended claims.

For example, while the orientations of the major surfaces of the active layers of the blue and green semiconductor laser elements are the (11-22) planes which are semipolar planes employed as exemplary non-C planes in each of the aforementioned first and second embodiments, the present invention is not restricted to this. According to the present invention, other non-C planes (non-polar planes or semipolar planes) may alternatively be employed as the surface orientations of the major surfaces of the active layers of the blue and green semiconductor laser elements. For example, non-polar planes such as m-planes ((1-100) planes) or a-planes ((11-20) planes), or semipolar planes such as (11-2x) planes (x=2, 3, 4, 5, 6, 8, 10, −2, −3, −4, −5, −6, −8 or −10) or (1-10y) planes (y=1, 2, 3, 4, 5, 6, −1, −2, −3, −4, −5 or −6) may be employed as the surface orientations of the major surfaces of the active layers of the blue and green semiconductor laser elements.

While the active layers of InGaN having the major surfaces of the (11-22) planes are formed on the upper surface of the n-type GaN substrate in each of the aforementioned first and second embodiments, the present invention is not restricted to this. According to the present invention, active layers of nitride-based semiconductors having major surfaces of non-C planes may alternatively be formed on the upper surface of a substrate made of Al₂O₃, SiC, LiAlO₂ or LiGaO₂.

While InGaN is employed as the “nitride-based semiconductor” in the present invention in each of the aforementioned first and second embodiments, the present invention is not restricted to this. According to the present invention, a nitride-based semiconductor such as AlInGaN or InAlN containing In or a nitride-based semiconductor such as AlGaN containing no In may alternatively be employed as the nitride-based semiconductor. In this case, the thicknesses and the compositions of the active layers of the blue and green semiconductor laser elements are properly changed.

While the barrier layers of the blue and green semiconductor laser elements are made of InGaN in each of the aforementioned first and second embodiments, the present invention is not restricted to this. According to the present invention, the barrier layers of the blue and green semiconductor laser elements may alternatively be made of nitride-based semiconductors such as GaN, AlGaN or AlGaInN having larger band gaps than the well layers.

While the well layers of InGaN are formed on the n-type GaN substrate in each of the aforementioned first and second embodiments, the present invention is not restricted to this. According to the present invention, the well layers of InGaN may alternatively be formed on an AlₓGa₁₋ₓN substrate. Spreads of the intensity distributions of the beams in a vertical/transverse mode can be suppressed by increasing the Al composition. Thus, emission of light from the AlₓGa_{1-y}N substrate can be suppressed, and hence each laser element can be inhibited from emitting a plurality of beams of the vertical/transverse mode. Further alternatively, the well layers of InGaN may be formed on an InₓGa_{1-y}N substrate. Thus, strains in the well layers can be reduced by adjusting the In composition in the InₓGa_{1-y}N substrate. In this case, the thicknesses of and the In compositions in the active layers of the blue and green semiconductor laser elements are properly changed.

While the semiconductor layers constituting the blue and green semiconductor laser elements are formed by selectively growing the same through the mask layers formed on the n-type GaN substrate in each of the aforementioned first and second embodiments, the present invention is not restricted to this. According to the present invention, the blue semiconductor laser element may alternatively be formed on the overall surface of the n-type GaN substrate and thereafter partly etched to partly expose the n-type GaN substrate, so that the green semiconductor laser element is formed on the exposed portion.

While the green semiconductor laser element is formed after the formation of the blue semiconductor laser element in each of the aforementioned first and second embodiments, the present invention is not restricted to this. According to the present invention, the blue semiconductor laser element may alternatively be formed after forming the green semiconductor laser element.

While ridge guided semiconductor lasers are formed by forming the p-type cladding layers having the ridge portions on the planar active layers and forming the current blocking layers which are insulating films on the side surfaces of the ridge portions in each of the aforementioned first and second embodiments, the present invention is not restricted to this. According to the present invention, ridge guided semiconductor lasers having current blocking layers of semiconductors, semiconductor lasers of an embedded heterostructure or gain guided semiconductor lasers including current blocking layers having striped openings formed on planar p-type cladding layers may alternatively be formed.

While the red semiconductor laser element is bonded onto the upper surface of the n-type GaN substrate in the junction-down manner to direct the p-n junction portion downward in the aforementioned second embodiment, the present invention is not restricted to this. According to the present invention, the red semiconductor laser element may alternatively be bonded onto the upper surface of the n-type GaN substrate in a junction-up manner to direct the p-n junction portion upward.

While the n-type GaN substrate and the active layers of the blue and green semiconductor laser elements are formed to have the major surfaces of the same non-C planes ((11-22) planes) in each of the aforementioned first and second embodiments, the present invention is not restricted to this. According to the present invention, the n-type GaN substrate and the active layers of the blue and green semiconductor laser elements may alternatively be formed to have major surfaces of different surface orientations.

While the active layer of the green semiconductor laser element has the SQW structure in each of the aforementioned first and second embodiments, the present invention is not restricted to this. According to the present invention, the active layer of the green semiconductor laser element may alternatively have an MQW structure.

While the n-type cladding layers, the n-type carrier blocking layers, the p-type carrier blocking layers and the p-type cladding layers of the blue and green semiconductor laser elements are made of AlGaN in each of the aforementioned first and second embodiments, the present invention is not restricted to this. According to the present invention, the n-type cladding layers, the n-type carrier blocking layers, the p-type carrier blocking layers and the p-type cladding layers of the blue and green semiconductor laser elements may alternatively be made of AlInGaN. In this case, the Al compositions in the n-type cladding layer, the n-type carrier blocking layer, the p-type carrier blocking layer and the p-type cladding layer of the green semiconductor laser element are preferably larger than those in the n-type cladding layer, the n-type carrier blocking layer, the p-type carrier blocking layer and the p-type cladding layer of the blue semiconductor laser element, respectively.

While the n- and p-type light guide layers of the blue and green semiconductor laser elements are made of InGaN in each of the aforementioned first and second embodiments, the present invention is not restricted to this. According to the present invention, the n- and p-type light guide layers of the blue and green semiconductor laser elements may alternatively be made of AlInGaN. In this case, the In compositions in the n- and p-type light guide layers of the green semiconductor laser element are preferably larger than those in the n- and p-type light guide layers of the blue semiconductor laser element, respectively.

While the In compositions in the n- and p-type light guide layers of the green semiconductor laser element are rendered larger than those in the n- and p-type light guide layers of the blue semiconductor laser element, respectively, in each of the aforementioned first and second embodiments, the present invention is not restricted to this. According to the present invention, the In compositions in the n- and p-type light guide layers of the green semiconductor laser element may alternatively be rendered smaller than those in the n- and p-type light guide layers of the blue semiconductor laser element, respectively.

While the Al compositions in the n- and p-type carrier blocking layers of the green semiconductor laser element are rendered larger than those in the n- and p-type carrier blocking layers of the blue semiconductor laser element in each of the aforementioned first and second embodiments, the present invention is not restricted to this. According to the present invention, the Al compositions in the n- and p-type carrier blocking layers of the green semiconductor laser element may alternatively be rendered smaller than those in the n- and p-type carrier blocking layers of the blue semiconductor laser element, respectively.

While the Al compositions in the n- and p-type cladding layers of the green semiconductor laser element are rendered larger than those in the n- and p-type cladding layers of the blue semiconductor laser element in each of the aforementioned first and second embodiments, the present invention is not restricted to this. According to the present invention, the Al compositions in the n- and p-type cladding layers of the green semiconductor laser element may alternatively be rendered smaller than those in the n- and p-type cladding layers of the blue semiconductor laser element, respectively.

While the blue semiconductor laser element, the green semiconductor laser element and the red semiconductor laser element are arranged successively from the side of the direction Y1 in the aforementioned second embodiment, the present invention is not restricted to this. According to the present invention, the arrangement of the blue semiconductor laser element, the green semiconductor laser element and the red semiconductor laser element is not particularly restricted. The red semiconductor laser element may alternatively be bonded onto the upper portion of the blue or green semiconductor laser element.

While the semiconductor laser device is constituted of one blue semiconductor laser element and one green semiconductor laser element (as well as one red semiconductor laser element) in each of the aforementioned first and second embodiments, the present invention is not restricted to this. According to the present invention, the semiconductor laser device may alternatively be formed by arraying a plurality of blue semiconductor laser elements and a plurality of green semiconductor elements (as well as a plurality of red semiconductor elements).

While the projector includes the optical system having the liquid crystal panels or the DMD in the aforementioned second embodiment, the present invention is not restricted to this. According to the present invention, the projector may simply include modulation means, and may be formed to include an optical system having a scanning mirror, for example.

What is claimed is:

1. A semiconductor laser device comprising:
a substrate;
a blue semiconductor laser element, formed on a surface of said substrate, including a first active layer made of a nitride-based semiconductor and having a first major surface of a non-C plane; and
a green semiconductor laser element, formed on said surface of said substrate, including a second active layer made of a nitride-based semiconductor and having a second major surface of a surface orientation substantially identical to said non-C plane.

2. The semiconductor laser device according to claim 1, wherein
said first active layer has a quantum well structure including a first well layer having a compressive strain,
said second active layer has a quantum well structure including a second well layer having a compressive strain, and
a thickness of said first well layer is larger than a thickness of said second well layer.

3. The semiconductor laser device according to claim 2, wherein
said first well layer is made of a nitride-based semiconductor containing In.

4. The semiconductor laser device according to claim 3, wherein
said first well layer is made of InGaN.

5. The semiconductor laser device according to claim 2, wherein
said second well layer is made of a nitride-based semiconductor containing In.

6. The semiconductor laser device according to claim 5, wherein
said second well layer is made of InGaN.

7. The semiconductor laser device according to claim 1, wherein
said non-C plane is substantially a (11-22) plane.

8. The semiconductor laser device according to claim 1, wherein
a third major surface of said substrate has a surface orientation substantially identical to said non-C plane.

9. The semiconductor laser device according to claim 1, wherein
said substrate is made of a nitride-based semiconductor.

10. The semiconductor laser device according to claim 2, wherein
a thickness of said first well layer is at least about 6 nm and not more than about 15 nm, and
a thickness of said second well layer is less than about 6 nm.

11. The semiconductor laser device according to claim 10, wherein
said first well layer is made of a nitride-based semiconductor containing In, and
an In composition in said first well layer is not more than about 20%.

12. The semiconductor laser device according to claim 11, wherein
said second well layer is made of a nitride-based semiconductor containing In, and
an In composition in said second well layer is larger than about 20%.

13. The semiconductor laser device according to claim 1, wherein
said blue semiconductor laser element further includes a first light guide layer containing In formed on at least either a side of one surface or a side of another surface of said first active layer,
said green semiconductor laser element further includes a second light guide layer containing In formed on at least either a side of one surface or a side of another surface of said second active layer, and
an In composition in said second light guide layer is larger than an In composition in said first light guide layer.

14. The semiconductor laser device according to claim 1, wherein
said blue semiconductor laser element further includes a first carrier blocking layer containing Al formed on at least either a side of one surface or a side of another surface of said first active layer,
said green semiconductor laser element further includes a second carrier blocking layer containing Al formed on at least either a side of one surface or a side of another surface of said second active layer, and
an Al composition in said second carrier blocking layer is larger than an Al composition in said first carrier blocking layer.

15. The semiconductor laser device according to claim 1, wherein
said blue semiconductor laser element further includes a first cladding layer containing Al formed on at least either a side of one surface or a side of another surface of said first active layer,
said green semiconductor laser element further includes a second cladding layer containing Al formed on at least either a side of one surface or a side of another surface of said second active layer, and
an Al composition in said second cladding layer is larger than an Al composition in said first cladding layer.

16. The semiconductor laser device according to claim 1, further comprising a red semiconductor laser element bonded to at least any of said blue semiconductor laser element, said green semiconductor laser element and said substrate.

17. The semiconductor laser device according to claim 1, wherein
said blue semiconductor laser element and said green semiconductor laser element further include light guides extending in directions projecting [0001] directions on said major surfaces.

18. The semiconductor laser device according to claim 1, wherein
said first major surface is a semipolar plane in said non-C plane, and
said second major surface is said semipolar plane.

19. The semiconductor laser device according to claim 18, wherein
said semipolar plane is a plane inclined toward a (0001) plane or a (000-1) plane by at least about 10° and not more than about 70°.

20. A display comprising:
a semiconductor laser device including a substrate, a blue semiconductor laser element, formed on a surface of said substrate, including a first active layer made of a nitride-based semiconductor and having a first major surface of a non-C plane and a green semiconductor laser element, formed on a surface of said substrate, including a second active layer made of a nitride-based semiconductor and having a second major surface of a surface orientation substantially identical to said non-C plane; and
means for modulating light emitted from said semiconductor laser device.
